(19) United States
(12) Patent Application Publication
(10) Pub. No.: US 2012/0142140 A1
(43) Pub. Date: Jun. 7, 2012

(54) NANOPARTICLE INKS FOR SOLAR CELLS

(75) Inventors: YUNJUN LI, Austin, TX (US); XUEPING LI, Austin, TX (US); JAMES P. NOVAK, Austin, TX (US)

(73) Assignee: APPLIED NANOTECH HOLDINGS, INC., Austin, TX (US)

(21) Appl. No.: 13/308,983

(22) Filed: Dec. 1, 2011

Related U.S. Application Data
(60) Provisional application No. 61/419,013, filed on Dec. 2, 2010.

(51) Int. Cl. H01L 31/18

(52) U.S. Cl. 438/98; 257/E31.124

(57) ABSTRACT

In a process for producing a solar cell, a sintering process performed on a nickel nanoparticle ink forms nickel silicide to create good adhesion and a low electrical ohmic contact to a silicon layer underneath, and allows for a subsequently electroplated metal layer to reduce electrode resistances. The printed nickel nanoparticles react with the silicon nitride of the antireflective layer to form conductive nickel silicide.

This application claims priority to U.S. Provisional Patent Application Ser. No. 61/419,013.

### TECHNICAL FIELD

The present invention relates in general to solar cells, and in particular, to processes for making solar cells.

### BACKGROUND

The current direction of silicon solar cell technology is to use thinner silicon wafers and improve conversion efficiency. The reduction in wafer thickness reduces overall material usage and cost because such materials account for almost 50% of the total cost of silicon solar cells. However, thin silicon wafers are often very brittle, and typical methods used for applying conductive feed lines, such as screen printing, are detrimental, since there is physical contact with the wafer.

Metallization is an important part of photovoltaic technology. To improve solar cell efficiency, the metallization processes of solar cells in manufacturing could utilize:

1. Further decreasing of contact resistance and increasing of metal-silicon contact areas.

2. Increasing of bulk conductivity of front grids with narrow width (<50 microns) to reduce light shadowing.

3. Lower cost materials by using less silver or replacing silver with low cost metals such as nickel and copper.

4. Low contact resistance metallization for all back contact solar cells by printing techniques to reduce manufacturing costs.

5. High manufacturing throughput.

### BRIEF DESCRIPTION OF DRAWINGS

FIG. 1 illustrates a partial cross-section of a structure of and process for producing a front contact solar cell device.

FIG. 2 illustrates a partial cross-section of a structure of and process for producing a back contact solar cell device.

FIGS. 3A-3C illustrate a partial cross-section of a structure of and process in accordance with embodiments of the present invention.

FIGS. 4A-4E illustrate a partial cross-section of a structure of and process for producing a solar cell device.

FIGS. 5A-5F illustrate a partial cross-section of a structure of and process for producing a solar cell device.

### DETAILED DESCRIPTION

Currently, about 180 micrometer thick wafers are used in manufacturing silicon solar cells. Metallization of these silicon solar cells is primarily accomplished using screen printing techniques. However, screen printing on wafers less than 180 micrometers thick will result in a very low manufacturing yield due to wafer breakage. If thinner wafers (e.g., as thin as 130 micrometers or less) could be utilized, then this would reduce the silicon usage and resultant cost of materials. The use of thin wafers requires new print processes and/or materials to be used in these new processes. Non-contact printing techniques for metallization of silicon solar cells will lead to less breakage (and resultant increased manufacturing yield) of such thinner silicon wafers. Metallic inks, such as nickel, silver, and aluminum inks, which can be applied to a silicon solar cell using non-contact printing techniques, screen printing, or dispensing techniques, are needed for the silicon solar industry. Embodiments of the present invention include metallic ink materials and a method to print a metallic layer by using non-contact printing techniques, such as inkjet printing and aerosol jet printing, to address the previously mentioned requirements.

Currently, the standard process for manufacturing silicon solar cells is based on screen printing of a metal paste, followed by firing it through an antireflective coating (“ARC”) on the front side. Typically, a p-type silicon wafer is doped with an n-type emitter layer on one side by thermal diffusion at a high temperature (e.g., >1000° C.) to form a p-n junction. The thickness of the n-type diffusion layer is typically less than 2 micrometers. Then, an antireflective coating with a thickness less than 100 nanometer, such as silicon nitride (SiNx), is deposited on the n-type emitter layer by chemical vapor deposition. This antireflective layer also acts as a passivation layer to reduce the surface recombination of minor carriers for better cell efficiency. Metal paste materials are used to create the electrical contacts on the front n-type emitter and backside of the p-type wafer. Aluminum paste is most commonly used for the hack side of the silicon and silver paste is most commonly used forming contacts on the front n-type emitter silicon. Then, both the aluminum paste on the back side and the silver paste on the front side are co-fired in an oven or belt furnace to form electrical contacts at a high temperature (e.g., from 700° C. to 910° C.). This silver paste may contain silver, glass frit, and organic components. The glass frit in the paste enables the forming of mechanical and electrical contacts on the n-type emitter of the solar cell by assisting the penetration of the silver into the insulating antireflective coating (SiNx). The silver-silicon electrical contacts are mostly from silver islands formed on the silicon substrate because diffused silver through SiNx results in non-uniform re-crystallized silver islands. Such resultant electrical contacts are not continuous, and it is very difficult to further reduce the electrical resistance at these contacts because of a relatively small portion of metallic contact area on the silicon. Moreover, this “firing through process” has very narrow processing windows, because silver paste is very sensitive to the firing temperature and time to penetrate the antireflective layer. Poor firing through of the antireflective layer will result in high contact resistance; or too much firing through will lead to damage or shunting of the p-n junction, decreasing cell efficiency. Therefore, providing a solution to achieve narrow electrodes and a higher conductivity than sintered paste is desired for improving cell efficiency. To further reduce material cost, copper may be utilized, since it is less expensive than silver, and its conductivity is as good as silver. However, migration of copper due to diffusion into silicon is severe and easily damages the shallow p-n junction, including completely disabling the photovoltaic effect, decreasing cell efficiency. Copper could be used for a silicon solar cell conductor but requires a barrier layer to prevent copper contact with the silicon and therefore diffusion into the silicon. Nickel, titanium, chrome, cobalt, etc., not only provide a good electrical contact on silicon, but also a good barrier layer for copper. The copper may be coated on top of the barrier layer. The top coating may be accomplished using a print or plating process. The barrier layer materials described above may be applied in very thin layers.

Table 1 provides a comparison of metal suicides created using materials that serve as a barrier layer for copper usage in solar cells. The table lists the suicide compositions, their electrical resistivities, their formation temperatures, and their Schottky harrier heights on silicon (Si). Table 1 shows that nickel silicide (NiSi) can be formed at lower temperatures and also has a lower Schottky barrier height on silicon than PtSi. This makes nickel an ideal material to form a low resistance contact on silicon at low temperatures (e.g., >600° C.). Nickel (Ni) may be utilized as a seed layer for plating to form such lower resistance contacts on the silicon, and thus can be used to replace silver, which is much more expensive. (See, J. P. Gambino et al. Mat. Chem. and Phys., 52(2), 99 (1998), which is hereby incorporated by reference herein.) Further, the low formation temperature of nickel silicide allows for manufacturing solar cells at a reduced energy usage. Also, low temperatures for processing of solar cells reduces the risk of metal diffusion damaging and/or shunting the underlying p-n junction, therefore increasing manufacturing yield. Moreover, nickel silicide improves the adhesion of a nickel layer to silicon due to the diffusion of nickel into the silicon on the interface.

TABLE 1

| Silicide | NiSi | NiSi₂ | TiSi | CoSi₂ | PtSi |
|---|---|---|---|---|---|
| Thin film resistivity | 14-20 | 35-50 | 13-20 | 14-20 | 28-35 |
| (μΩ · cm) | | | | | |
| Formation temperature | 400-600 | 600-700 | 600-700 | 600-700 | 300-500 |
| (° C.) | | | | | |
| Schottky barrier height | 0.67 | 0.7 | 0.6 | 0.64 | 0.87 |
| on Si (eV) | | | | | |

Nickel can be electroless-plated on an etched silicon nitride antireflective layer of silicon solar cells. However, the patterning and etching processes for a silicon nitride layer are costly and time consuming because an expensive photolithographic process is typically needed to pattern silicon nitride. The ARC layer may also be ablated into a desired pattern on the silicon using a laser. These processes possess lower manufacturing throughput and increased manufacturing cost when compared to printing techniques.

Applying metallic ink or paste by inkjet or aerosol jet printing (or other printing techniques, such as dispensing techniques and screen printing) eliminates the patterning and etching processes for producing conductive electrodes on silicon solar cells. During a print-based metallization process, the metal paste or ink is placed upon a silicon substrate. A particular desired pattern is determined by the individual print process. A paste-based material has a viscosity greater than 1000 centipoise (CP). The paste material is printed with a screen printer, which may have a screen mesh pattern defined by a polymer film. This polymer film defines a pattern that excludes paste from being pushed through, in contrast to an open screen wire mesh that has no polymer coating. A metallic ink has a viscosity less than 1000 centipoise. Ink materials may be printed using non-contact printing techniques. Non-contact printing is generally patterned using a computer controlled digital process, which controls a position of the print nozzle and switches on or off the ink flow therefrom. Spray printing is also a non-contact printing technique, which may be used for coating large areas where no pattern is required.

Metallic inks or pastes are comprised of small metal particles and/or metal nanoparticles and may also include one or more of solvents, viscosity modifiers, vehicles, binders, dispersants, and/or other ingredients. Small metal particles typically have a size less than 2 micrometers in diameter, clown to 100 nm. Metal nanoparticles have a diameter less than 100 nm. A bulk metal material has particle sizes in all dimensions greater than one micrometer.

After the metallic ink or paste is printed onto a substrate, the ink or paste is processed to convert the discrete particles used in the printable form into a singular conductive feature. This processing may be sintering, curing, or melting. During these processes, the volatile components of the paste or ink (e.g., solvents, vehicles, etc.) are removed as the process temperature increases. Next, each type of process has different temperature ranges for completion, resulting in different final structures and performance.

During a sintering process, the surfaces of the metal nanoparticles melt into their nearest neighboring particles without fully melting the entire core of the particle. Sintering usually creates a porous network of interconnected particles, which form a conductive pathway through the metallic feature. Sintering processes are performed with sufficient energy to react particles with a silicon substrate.

Curing processes occur at low temperatures, wherein non-metallic components of the ink or paste are removed or reacted, yet a majority of the metallic components retain the same physical form as before the curing process. For example, solvents may evaporate, binders are reactive, and particles may still be discrete.

During a melting process, there is sufficient energy to cause complete particles to flow into a nearly continuous film, having a porosity of less than 20% void space. Bulk metal, small metal particles, and metal nanoparticles all have different melting temperatures. The melting point of nanoparticles (less than 100 nm) of a metal is significantly less than the melting point for the bulk metal, resulting in lower required sintering temperatures for an ink comprised of such nanoparticles. For example, the melting point of bulk nickel is 1400° C., but nickel nanoparticles can be sintered and/or fused at temperatures as low as 500° C. or lower. Thus, the resistivity of the printed ink may be reduced by fusing the metallic nanoparticles together through sintering at much lower temperatures compared to the bulk melting temperature of the base metal. As the temperature is increased, there is a transition from sintering to melting. Melting occurs when all of the particle is melted. Sintering occurs when just the surface of the particle melts and the core of the particle does not. The ability to lower the process temperature through the reduction in metallic particle size is important for controlling the diffusion of the metal into the silicon. Controlling the diffusion of metal in a silicon solar cell is important to prevent diffusion-based shunting. Additionally, lower temperatures reduce energy consumption during manufacturing resulting in reduced manufacturing cost. Ideal nickel silicide is formed at temperatures from approximately 400° C. to 600° C. Nanoparticles can also be sintered or fused at temperatures from approximately 400° C. to 600° C. to form both a good conductive film and a low resistance contact on silicon. For micron-sized (i.e., larger than nanoparticles) nickel particles, much higher temperatures over 800° C. may be required to form a good conductive film, which is not suitable for solar cell manufacturing, because at these higher temperatures, nickel diffusion is severe and will easily damage the underlying p-n junction.

A sintering process performed on a nickel nanoparticle ink forms nickel silicide to create good adhesion and a low electrical ohmic contact to silicon, and allows for a subsequently electroplated metal layer to reduce electrode resistances. Under certain temperatures and assisted by a certain catalyst (e.g., titanium, tantalum, palladium, or gallium (nanoparticles or a soluble compound containing the catalyst)), the printed nickel nanoparticles react with the silicon nitride (e.g., the antireflective layer) to form conductive nickel silicide, as follows:

Ni+N→NiSi+N↑(Gas)

SiNₓ, typically grown by chemical vapor deposition or plasma enhanced chemical vapor deposition, may be amorphous or crystalline in the above reaction formula. With this approach, during a sintering process, printed nickel nanoparticles convert insulating silicon nitride into conductive nickel silicide, and the diffused nickel also thrills nickel silicide on the silicon underneath the silicon nitride. With the foregoing, an etching process for silicon nitride is avoided.

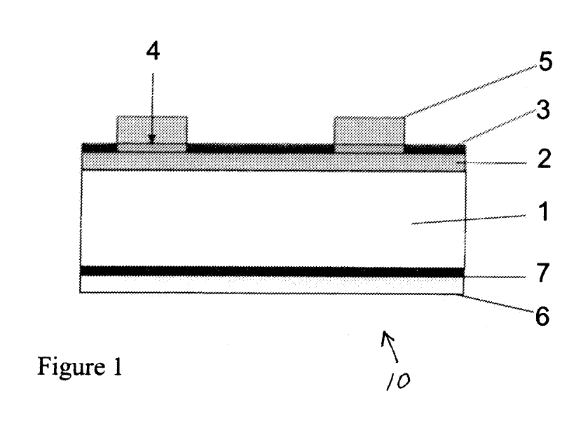

FIG. 1 illustrates a structure and process for printing a metallic ink (e.g., nickel ink) on a front side of solar cells for front contact solar cell manufacturing (the front side of a solar cell is the side that is designed to receive the light energy that the cell uses to convert to electrical energy). The solar cell device 10 may be produced by using a p-type silicon (mono or polycrystalline) semiconductor substrate 1. An n-type emitter layer 2, which may be formed by doping phosphor with a high temperature diffusion process, is produced after chemical surface treatments or a surface texturing process. Such a chemical treatment may expose the silicon substrate surface to acid (nitric and hydrofluoric mixture) creating a textured surface (e.g., a pyramidal shape), which decreases the amount of reflectance of the silicon substrate surface. Then, an antireflective and passivation layer 3, which may be a silicon nitride layer produced by chemical vapor deposition, is formed on the n-type layer 2. A metallic (e.g., nickel) layer 4 is then printed by a non-contact printing technique (e.g., inkjet or aerosol jet printing) or a dispensing or screen printing technique on the passivation layer 3. The non-contact printing process uses a metallic ink (e.g., nickel ink), and the contact screen printing process uses a metallic paste (e.g., nickel paste). There are at least two types of metallic inks that may be used to form a low resistance contact on the n-type layer 2. One type of metallic ink is printed on an etched passivation layer, which may be processed by a photolithographic method or printed ink containing etchant to etch through the passivation layer 3. This type of ink (Ink Formulations 1 and 2 described hereinafter) is printed on the etched areas to form a low contact resistance layer on the n-type layer 2. Another type of ink (Ink Formulation 3 described hereinafter) containing an etchant or glass is used to etch through the passivation layer 3 and form a low contact resistance at the same time when it is sintered at a low temperature. A collecting electrode 5 (e.g., a nickel layer) is then formed on the printed metallic layer 4. The front grid electrodes 5 may be plated or printed by using metallic (e.g., silver) inks or pastes. Aluminum ink may be printed as a back contact electrode 6.

The front grid electrodes 5 and back contact 6 may be co-fired or fired separately, as has been previously described. The firing results in a low resistance contact formed between the layer 4 and the n-type layer 2. An aluminum-silicon alloy and BSF (back surface field) layer 7 may be also formed in the interface between the aluminum layer 6 and the p-type silicon substrate 1 by diffusion during the tiring process.

For printing nickel inks for solar cell manufacturing, an alternative process is to first print the aluminum layer 6 on the solar cell structures with a formed n-type emitter and deposited passivation layer. Then, an aluminum electrode is fired to form the BSF layer 7 with a belt furnace or an oven (e.g., at temperatures from approximately 700° C. to 910° C.) in atmosphere. Then, the nickel layer is printed on the passivation layer and sintered between approximately 350° C. and 600° C. in an oven with a reducing and/or forming gases containing hydrogen to form a low resistance contact on the n-type layer 2. Sintering is further disclosed in U.S. Published Patent Application Nos. US 2008/0286488 and US 2009/0311440, which are both hereby incorporated by reference herein. The nickel ink may be printed on the passivation layer with narrow feedlines and wide bus bars. The narrower feedlines printed by inkjet printing produce less shadowing from incident sun light on the front side of solar cells, therefore increasing cell conversion efficiency. When fired under the right conditions, the metallic particles are sufficiently sintered to form a highly conductive continuous film, which can easily transport electrons or holes generated by the silicon solar cell. Achieving low resistance is important for producing a highly efficient solar cell; therefore, producing a highly conductive nickel layer with a secondary layer with higher conductivity is required, since nickel is not as conductive as the industry standard silver. A silver, or copper, on nickel layer may then be deposited using an electroplating process or light-induced plating to form highly conductive metal electrodes, which have a low resistivity close to bulk metal, therefore reducing the series resistance and improving the efficiency of the solar cell. Low series resistance reduces the heat losses in solar cells during their operation. Electroless plating may utilize an auto-catalytic chemical technique to deposit a layer of metal. The silicon substrate containing the nickel layer is immersed in a metal salt solution. A reducing agent, typically sodium borohydride, is used to chemically reduce the metal salt to metal. This reduced metal layer preferentially plates on top of the existing metallic layer.

Additional plating may be performed using electricity. Electroplating is similar to the electroless plating whereby the metal layer is immersed in a chemical metal salt solution. The existing nickel layers are connected to a power supply. Using a voltage greater than the reduction potential of the specific metal, the metal salt is reduced into a layer of metal on the surface of the printed electrode. Another variation of electroplating is light-induced plating (LIP). LIP takes advantage of the photovoltaic effect in the solar cell. The solar cell is illuminated with light while immersed in the plating metal salt solution. The internal voltage generated by the solar cell drives the reduction of the metal salt to metal. LIP eliminates the need for an external power supply to facilitate electroplating. Plating with copper may be substituted as a cost-effective process to replace silver in order to drop the material cost.

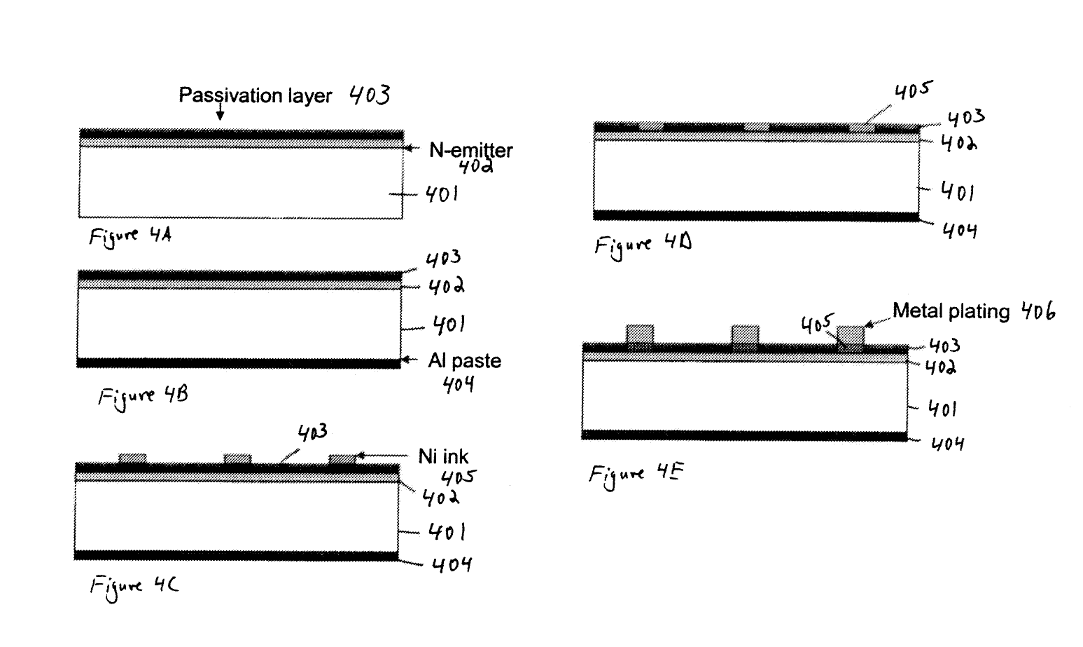

Referring now to FIGS. 4A-4E, there is illustrated an alternative process. FIG. 4A illustrates a solar cell structure with a formed n-type emitter 402 and deposited passivation layer 403 on a silicon substrate 401 as similarly disclosed herein. In FIG. 4B, an aluminum layer 404 is printed on the solar cell structure. Then, a nickel layer 405 as a seed layer (the seed layer is used as a conductive layer to be plated with metal by an electroplating process) is printed on the passivation layer 403 for forming a low resistance contact on the n-type layer 402 underneath the passivation layer 403 (FIG. 4C). The seed layer may be a very thin layer of metal that is used to act as a base layer for a secondary print or plating. This seed layer may be less than 1 micrometer thick, but may be up to 8 microns thick depending on the method of deposition. The seed layer has less thickness than the secondary print or plating layer. Referring to FIG. 4D, after printing, the printed aluminum electrode 404 may be co-fired to form the BSF layer along with the printed nickel front contact 405. Then, the co-fired solar cells may be further treated in a reducing environment to reduce the oxidized nickel in the front into metallic nickel at a temperature from approximately 300° C. to 600° C. Essentially, in this process, hydrogen may be utilized to reduce nickel oxide into metallic nickel at a relatively high temperature. The reducing environment may be a mixture of 4% hydrogen with the remaining gas inert, such as nitrogen or argon. The hydrogen reacts with the surface oxide of the metal to create water. A clean metal surface free of oxide results after firing the metal in the reducing atmosphere. Referring to FIG. 4E, a silver, or copper, on nickel layer 406 may be deposited using an electroplating process or light-induced plating to form the highly conductive metal electrodes with resistivity close to bulk metal, therefore reducing the series resistance and improving cell efficiency.

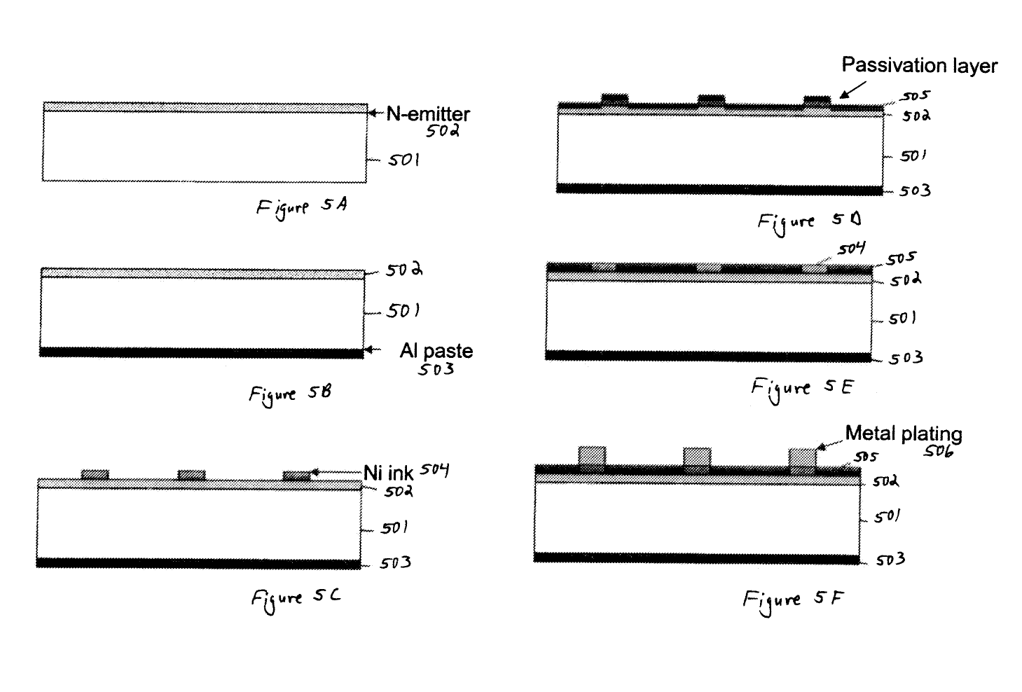

FIGS. 5A-5F illustrate another alternative process in which a metallic ink (e.g., nickel ink) is printed before passivation deposition. FIG. 5A illustrates a silicon wafer 501 with an n-type emitter 502. Referring to FIG. 5B, metallic paste (e.g., aluminum paste) 503 is printed by screen printing on the back side of the solar cells. Though screen printing has a higher risk or breakage rate to break thin wafers than non-contact printing, screen printing paste is feasible for this case. Referring to FIG. 5C, after drying of the aluminum paste 503 (e.g., by using an oven or belt furnace in atmosphere at a temperature below 250° C.), metallic ink (e.g., nickel ink) 504 is printed by using either inkjet printing or screen printing on the n-emitter 502 (e.g., with a pattern of narrow feedlines and wide bus bars). Referring to FIG. 5D, after drying of the nickel ink 504 (e.g. by using an oven or belt furnace in atmosphere at a temperature below 250° C.), an antireflective and passivation layer 505 is deposited on the front side of the solar cells to cover the emitter 502 and printed nickel electrodes 504 (e.g., a grid of narrow feedlines and wide bus bars). The antireflective layer 505 (e.g., silicon nitride (SiNx), silicon oxide (SiOx), or aluminum oxide (Al₂O₃)) may be deposited using plasma chemical vapor deposition or plasma-assisted atomic layer deposition (PA-ALD). Referring to FIG. 5E, the solar cell structure is co-fired to form an ohmic contact on the n-emitter and back side of the solar cells. A further annealing (e.g., at temperatures from approximately 350° to 600° C.) in reducing gases in an oven may be utilized to achieve further decreased contact resistivity and sheet resistance for the nickel ink on the emitter. During the firing process, the thin insulating antireflective layer 505 on the top of the nickel ink 504 is broken (i.e., the thermal expansion mismatch between nickel nanoparticles and antireflective layer is very large; sintering causes the antireflective layer to become discontinuous, therefore underlying nickel is exposed) or converted into conductive nickel suicide by chemical reaction with the silicon nitride, as described by the reaction equation:

Ni+SiNₓ→NiSi+N₂↑(Gas)

Therefore, conductive nickel and nickel silicide is exposed as a conductive surface over the printed nickel electrodes 504 because nickel reacts with silicon nitride to from conductive nickel silicide during the sintering process. Referring to FIG. 5F, electroplating or light-induced electroplating may be utilized to plate thick copper or silver layers 506 on the exposed conductive nickel and nickel silicide to decrease the electrode resistance and series resistance of solar cells, since thick plated copper or silver will create very low sheet resistance of electrodes to minimize the voltage drop or heat loss for the solar cells. Decreased resistance in the solar cell increases solar conversion efficiency.

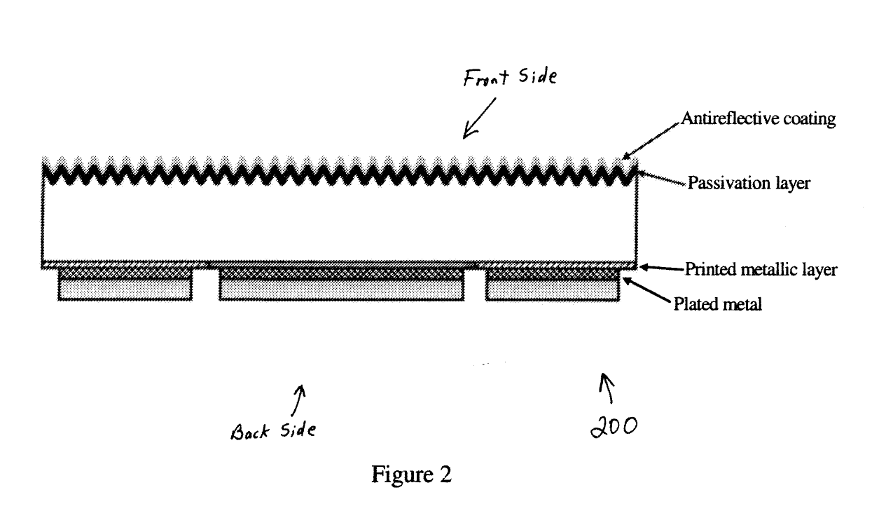

FIG. 2 illustrates a partial cross-sectional structure of a solar cell structure 200 showing how metallic ink has been utilized for interdigitated all back contact solar cell manufacturing. Rear junction, interdigitated back contact (“IBC”) solar cells have several advantages over front contact solar cells having contacts on both sides. Moving all the contacts to the back of the solar cell eliminates shading of incident of light from the front contacts, leading to a higher short-circuit current. With all the contacts on the back of the solar cells, series resistance losses are offset by the reduced reflectance at the front surface and the larger contact area on the back surface. Having all the contacts on the back side simplifies solar cell integration during module fabrication and improves the packing factor because the positive and negative electrodes of the solar cells are all located on the back of the cells and are easily connected together to make solar panels. Typical solar cells have the positive electrode on the front and the negative electrode on the back. Large gaps in between adjacent solar cells are needed for the inclusion of electrical wires connected from back to the front to make the solar panel. Also, reduced stress on the wafers with interdigitated electrodes during interconnection improves yield because typical solar cells have a blanketing aluminum layer on the back that suffers from bowing due to the thermal mismatch between silicon and aluminum, which would be especially disadvantageous for large thin wafers.

Even though solar cells with interdigitated back contacts have a cell efficiency over 23%, the manufacturing cost is much higher than traditional solar cells, which use low-cost printing techniques. Interdigitated back contacts are currently fabricated by vacuum deposition and patterned by lithographic processes, which are costly with limited capacity for implementing lower manufacturing cost techniques. Nickel ink may also be printed for all back contact solar cell manufacturing to form low ohmic contacts on both 11-type and p-type silicon. Nickel and aluminum are two materials that are inexpensive and form low resistance contacts on both n-type and p-type silicon. An advantage to using a single metal for both contacts on a solar cell is reduced material cost. For interdigitated backside contact (IBC) cells it is difficult to apply two different metal conductors on a single side of the wafer with different patterns. The ability to metallize both the both n-type and p-type silicon on one side of the wafer using a single print step and a single metallic ink is important to realizing high efficiency, low cost cells. Most IBC cells us a metallization step that involves a vacuum based metallization process, such as physical vapor deposition (PVD). This process is slow and expensive in comparison to printing metallic contacts. Nickel nanoparticle ink can be sintered or fused to produce a highly conductive film and form silicide on silicon at the same time at low temperatures. Also, because nickel silicide also has a lower Schottky barrier height on silicon than other metals at low sintering temperatures, sintered nickel nanoparticles create a lower contact resistance on silicon. This makes nickel an ideal material to form a low contact resistance on silicon at low temperatures (e.g., <600′C). With a single ink and single print (manufacturing traditional solar cells requires at least two prints and uses two different inks to make solar cells (i.e., one ink to print front side silver and a second ink for the back side aluminum), the ink can produce a low resistance contact on both n-type and p-type fingers for IBC solar cells after sintering. To obtain further increased conductivity, an electroplating process may be used to thicken the electrodes on a printed and sintered conductive nickel, or aluminum layer on all back contact solar cells.

### Ink Formulation 1: Metallic Nanoparticle Ink for Inkjet Printing

A nickel ink for inkjet printing may be formulated with nickel nanoparticles, solvents, dispersants, binder materials, and other functional additives. A dispersant may be used to de-agglomerate nanoparticles in inks. Binder materials may be used to improve adhesion of the sintered nanoparticle inks on the substrates. Other functional additives may be added to help form suicide or assist nickel diffusion through the thin insulating layer to form an electrical contact with the silicon underneath. The sizes of the nickel nanoparticles may be below 500 nm, preferably below 100 mm, more preferably below 50 nm. The smaller the particle size, the lower the required sintering temperature to form a conductive film, and the better the inkjettibility of the formulated inks. The vehicle may include one solvent, or a mixture of solvents, containing one or more oxygenated organic functional groups, one alcohol, and/or ether. The solvents are a vehicle to suspend the nanoparticles in the ink and keep individual nanoparticles apart by assisting with dispersant. The oxygenated organic compounds may be medium chain length aliphatic ether acetate, ether alcohols, diols and triols, cellosolves, carbitola, or aromatic ether alcohols. Oxygenated organic compounds are polar in nature. These various oxygenated organic functional groups have chemical interactions with the oxide surfaces of the metal particles through mechanisms including surface adsorption, chemical adsorption, physical adsorption, hydrogen bonding, and ionic bonding. The acetate may be chosen from a list of 2-butoxyethyl acetate, propylene glycol monomethyl ether acetate, diethylene glycol monoethyl ether acetate, 2-ethoxyethyl acetate, and ethylene glycol diacetate. The alcohol may be chosen from a list of benzyl alcohol, 2-octonal, isobutonal, and equivalent alcohols. To avoid the fast drying of the ink, which would clog the dispensing inkjet head, the chosen compounds may have boiling points ranging from approximately 100° C. to 250° C.

The weight percentage of dispersants may vary from approximately 0.5% to 10%. The quantity of dispersant is determined by the surface area of the particles. Particle surface area varies as a function of its diameter. Dispersant quantity may be adjusted to ensure adequate coverage of the particles without significant excess of material in the mixture.

The dispersant may be chosen from organic compounds containing ionic functional groups, or a carboxylic polyester block copolymer, which can be found in commercially available dispersants such as Disperbyk 180, Disperbyk 111, and Disperbyk 110. Non-ionic dispersants, which have a hydrophilic polyethylene oxide group R—O(C₂H₄O)ₙ (5≦n≦20), octylphenol ethoxylate, ethoxy (oxy-1,2-ethanediyl) group, may be chosen from a commercially available list of Triton X-100, Triton X-15, and Triton X-45, respectively, liner alkyl ether (colar Cap MA259, Colar Cap MA 1610), quaternized alkyl imidazoline (Cola Solv IES and Cola Solv TES), and polyvinylpyrrolidone (PVP). The loading concentration of nickel nanoparticles may be from approximately 10% to 60%. The different loading of nickel particles changes the mass delivery of nickel to the substrate. Some printed substrates require different thicknesses of line traces. For example, a seed layer application may require a minimum thickness of ink and therefore require a low mass loading concentration.

The formulated ink is mixed (e.g., by sonication or other high shear mixing processes, and then may be ball-milled to further the dispersion). The formulated nickel inks may be passed through a filter (e.g., with a pore size of 1 micrometer) to eliminate any large aggregated nanoparticles in the ink to avoid clogging the printing head. An embodiment of nickel ink for inkjet printing is formulated with 2-butoxyethyl acetate, benzyl alcohol, Disperbyk 111, and nickel nanoparticles with a size below 100 nm. Table 2 shows the ink properties of the nickel ink.

TABLE 2

| | | Surface | Contact | |
|---|---|---|---|---|
| | Viscosity | tension | angle on | Resistivity |
| Ink | (CP) | (dyne/cm) | polyimide | (μΩ · cm) |
| Nickel | 8-20 @ 12 rpm | 30-32 | 10° | 30 (photo- |
| nanoparticle | and 25° C. | | | sintering) |
| ink | | | | 20 (thermal |
| | | | | sintering) |

Table 2 shows the physical properties of the nickel ink formulation and its resistivity after it has been sintered. The viscosity of the nickel ink for inkjet printing is approximately 8-20 CP. The nickel ink has a surface energy of approximately 30 dyne/cm to reduce the accumulation of the ink around the nozzles of the inkjet printing head. The contact angle measured on a polyimide substrate is approximately 10°. The printed ink may be sintered by photosintering, such as with a flash lamp or laser. The nickel ink formulation in Table 2 was photosintered using a xenon flash lamp using a 1.5 kV power input and a 2 ms timescale. Similar results can be achieved using shorter pulse widths and increased voltage. Also, the ink may be sintered in a furnace with forming or reducing gases containing hydrogen. The nickel ink formulation shown in Table 2 was thermal sintered in an infrared tube furnace at 400° C. in a forming gas (4% H₂ in N₂) environment. As shown in Table 2, the resistivity is lower when thermal sintered. This process is good for silicon solar cell applications as it is compatible with existing manufacturing practice while decreasing the overall solar cell resistance.

The ink may be inkjettable (e.g., with a Dimatix inkjet printer) on silicon substrates or plastic substrates, such as polyimide. After printing a metallic ink solution on a substrate surface, the ink may be pre-cured or dried. The pre-curing may be performed at temperatures generally less than 200° C. The ink also may be dried at high temperatures in an oven or with an infrared lamp to dry for a short time, at less than 250° C. The ink solution may be cured in air or other gas environments such as nitrogen, hydrogen, or argon. The resistivity of the printed ink may be further reduced by fusing the metallic nanoparticles together through sintering at much lower temperatures (e.g., 350° C.) than their counterpart bulk metals. For example, the melting point of bulk nickel is 1400° C., while nickel nanoparticles can be sintered and/or fused at temperatures as low as 500° C. or lower. The ink can be sintered at temperatures greater than 500° C., however lower temperature is preferred.

Binder materials may be used in the ink to promote adhesion to the substrate. Binder materials can serve secondary functions by having reactive properties within the ink or between the metallic ink or paste and the substrate. The binder material may be curable inorganic polymers or low softening-point glass. Low softening point glass materials are used as binder additives within inks and paste primarily for their reactive properties with silicon nitride ARC coatings. The commonly agreed mechanism is that the glass reacts with the silicon nitride white at elevated temperature. This reaction creates oxide or oxynitride structures that allow the metallic components in the ink or paste to diffuse through the nitride layer forming an electrical contact between the metal and the silicon. The low-softening point glass may be chosen from series of glass PbO/B₂O₃/SiO₂ or PbO/B₂O₃/Bi₂O₃ or SnO/B₂O₃ or Ag₂O/V₂O₅/TeO₂/PbO, or lead-free B₂O₃—ZnO—BaO—Bi₂O₃ glass or SnO/P₂O₅/MnO, which has a softening point below 450° C., and more preferably has a softening point below 350° C. The sizes of the glass powders may be less than 500 nm, preferably below 100 nm. The glass ingredient enhances the adhesion strength between the metallic layer and the silicon. The loading concentration of glass may be from approximately 0.5% wt. to 10% wt. The process temperature is matched to the specific softening temperature of the glass and the specific nitride composition on the surface of the wafer. The specific loading concentration of the glass frit is dependent on the thickness of the ARC coatings. A native passivation layer will require 0.5% binder and a thick (greater than 90 nm) ARC will require up to 10% binder. The binder concentration is also dependent on the mass loading of nickel particles.

Inorganic polymer may be selected from one of polysiloxane-based polymers, such as rigid ladderlike poly(phenylsilsesquioxane) (“PPSQ”). Such an inorganic polymer, such as PPSQ, may be dissolved in alcohols, acetates, or ethers, and will homogeneously distributed in inks and do not need to worry about the dispersion in inks. The polysiloxane-based polymer can form a strong bonding to silicon because of its Si—O bond in its main polymer chain. Also, this material has a very good thermal stability up to 500° C. to secure long term reliability even at harsh environment service.

The nickel may be thermal sintered in a forming gas or inert environment and/or photosintered in atmosphere. Laser sintering may be used for sintering nickel ink. A resistivity of at least 2×⁻⁵ Ω.cm has been achieved by both thermal sintering and photosintering techniques. Relatively good contact resistance may also be obtained on silicon with printed nickel inks, as shown in Table 3. Nickel ink was printed on both n-type and p-type monocrystalline silicon wafers and sintered in reducing gases containing hydrogen. The sintering temperature may be below 600° C., preferably below 500° C., and even as low as 350° C. To measure contact resistance, the nickel ink was printed on silicon wafers with a transmission line method (“TLM”) pattern. The printed TLM patterns may be sintered in a forming gas environment with a furnace. The forming gas may contain hydrogen and other inert gases such as nitrogen or argon. After sintering at low temperature, low sheet resistivity and contact resistivity were obtained for the nanoparticle nickel ink, as shown in Table 3.

TABLE 3

| | | | Specific Contact | |
|---|---|---|---|---|
| Silicon | Ni Resistivity | Ni Thickness | Resistivity | Sintering |
| wafer | (Ω · cm) | (μm) | (Ω · cm²) | Conditions |
| p-type | 2.5 × 10⁻⁵ | 1.8 | 3.3 × 10⁻² | 350° C. in |
| | | | | forming gas; |
| | | | | 20 mins |
| n-type | 4 × 10⁻⁵ | 0.6 | 3.9 × 10⁻² | 350° C. in |
| | | | | forming gas: |
| | | | | 20 mins |
| poly- | N/A | 0.2 | 2.6 | 450° C. in |
| silicon | | | | forming gas: |
| | | | | 20 mins |

### Ink Formulation 2: Metallic Nanoparticle Ink for Aerosol Jet Printing

Nickel ink for inkjet printing may be formulated with nickel nanoparticles, solvents, dispersants, binder materials, and/or functional additives. The sizes of aluminum nanoparticles may be below 500 nm, preferably below 200 nm, and more preferably below 50 nm. The vehicle may include one solvent or a mixture of solvents containing one or more oxygenated organic functional groups, one alcohol, and/or ether. The oxygenated organic compounds refer to medium chain length aliphatic ether acetate, ether alcohols, diols and triols, cellosolves, carbitola, or aromatic ether alcohols. The acetate may be chosen from the list of 2-butoxyethyl acetate, propylene glycol monomethyl ether acetate, diethylene glycol monoethyl ether acetate. 2-ethoxyethyl acetate, and ethylene glycol diacetate. The alcohol may be chosen from a list of benzyl alcohol, 2-octonal, terpineol, di(propylene glycol) methyl ether, isobutonal, and the like. The chosen compounds have boiling points ranging from approximately 100° C. to 250° C. Table 4 shows the physical properties of the nickel ink formulation and its resistivity after it has been sintered.

TABLE 4

| | | Surface | Contact | |
|---|---|---|---|---|
| | Viscosity | tension | angle on | Resistivity |
| Ink | (CP) | (dyne/cm) | polyimide | (μΩ · cm) |
| Nickel | 90-200 @ 12 rpm | 30-32 | 10° | 35 (photo- |
| nanoparticle | and 25° C. | | | sintering) |
| ink | | | | 20 (thermal |
| | | | | sintering) |

The weight percentage of dispersants may vary from approximately 0.5% to 5%. The dispersant may be chosen from organic compounds containing ionic functional groups, such as such as Disperbyk 180, Disperbyk 111, Disperbyk 110, anti-Terra-100. Non-ionic dispersant may also be chosen from a list of Triton X-100, Triton X-15, Triton X-45, Triton QS-15, liner alkyl ether (colar Cap MA259, Colar Cap MA1610), quaternized alkyl imidazoline (Cola Solv (ES and Cola Solv TES), and polyvinylpyrrolidone (PVP). The loading concentration of nickel nanoparticles may be from approximately 10% to 70%. Anti-settling agents may also be added, such as Disperbyk 410 with a concentration from approximately 0.2 to 3%.

Other functional additives, such as an etching agent or a low softening-point glass to etch through the passivation layer, may be also added into such nickel nanoparticle inks. The weight percent of low soft point glass may range from 0.5% to 5%. The etching agents may contain phosphoric acid, fluorine, or organophosphate, which may be dissolved in solvents that are used for the inks. The etching agent is used to allow metallic nanoparticles to diffuse through insulating passivation layer to form ohmic contact on underneath n-type or p-type silicon. A certain catalyst, such as titanium, tantalum, palladium, and gallium may also added into the ink to help the printed nickel nanoparticles react with silicon nitride to form conductive nickel silicide. The weight percent of the catalyst in ink may range from 1% to 15%. The catalyst may be nanoparticles or soluble compounds containing titanium or tantalum or palladium or gallium.

### Ink Formulation 3: Metallic Nanoparticle Ink for Etching Passivation Layer

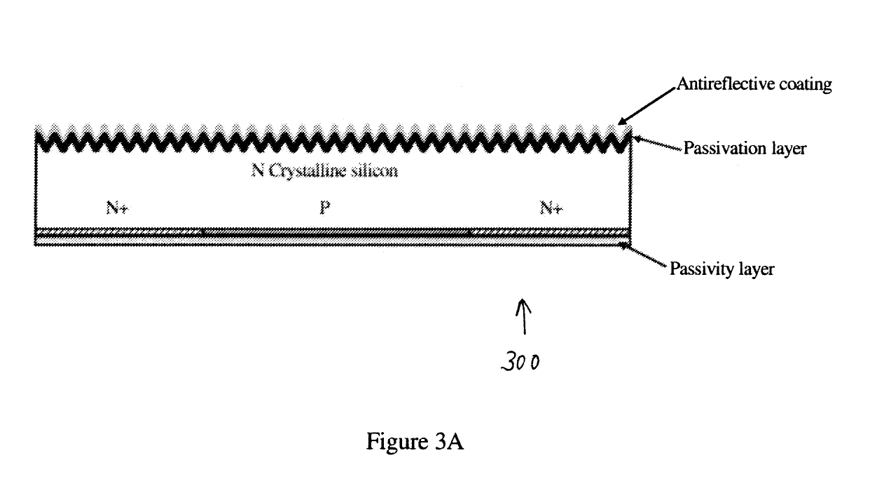

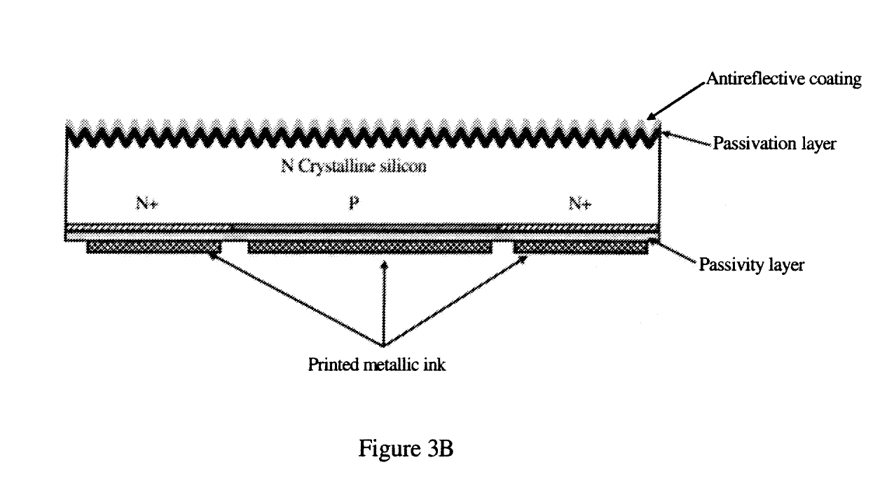

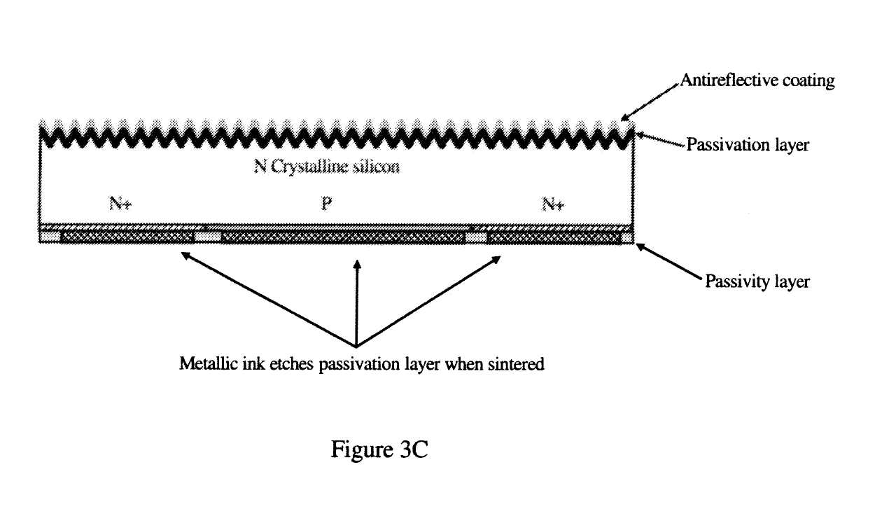

Referring to FIG. 3A, a passivation layer of silicon nitride or silicon oxide may be deposited on p-type zone (positive electrode) and n⁺ zone (negative electrode) of IBC solar cells 300 to reduce recombination to improve cell efficiency. To form an ohmic contact, a photolithographic process may be used to open the insulating passivation layer for depositing a metallic film to form an electrical contact on the p and n⁺ zones. This photolithographic process is not cost-effective and has low manufacturing throughput. By using metallic inks, the ink can be directly printed on the p and n⁺ zones and eliminate this costly process. However, to form an electrical contact through an insulating passivation layer on a silicon solar cell, metallic ink is required that not only etches through the passivation layer but also forms a low contact resistance after sintering. The metallic nanoparticles inks disclosed herein may be used to etch through the passivation layer and form low contact resistance at the same time when it is sintered at low temperature, as described with respect to FIGS. 3B and 3C. The sintering temperature may be lower than 600° C., preferably less than 450° C. more preferably less than 350° C. To further reduce the series resistance of the solar cells, this metallic layer can function as a seed layer for electroplating copper or silver to increase the conductivity of the electrodes.

Metallic nanoparticle ink, such as nickel ink, may be formulated with nickel nanoparticles, solvents, dispersants, binder materials, functional additives, etching agent for passivation layer, and/or low softening point glass. The passivation layer may be silicon nitride, silicon oxide, or titanium oxide. The etching agents for silicon nitride may contain phosphoric acid or compounds containing fluorine, or organophosphate. During sintering, the etching agent reacts with silicon nitride to allow metallic nanoparticles to diffuse through insulating passivation layer to form ohmic contact on underneath n-type or p-type silicon. A catalyst, such as titanium, tantalum, palladium, and gallium may also be added into the ink to help the printed nickel nanoparticles react with silicon nitride to form conductive nickel silicide. The weight percent of the catalyst may range from 0.5% to 15%. A low softening-point glass to etch through the passivation layer, may be also added into such nickel nanoparticle inks. The weight percent of low soft point glass may range from 0.5% to 5%.

Another embodiment is an aqueous nanoparticle ink that is formulated with metallic nanoparticles, water, dispersant, binder material, functional additives, etching agent for passivation layer, and/or low softening point glass. The passivation layer may be silicon nitride, silicon oxide, or titanium oxide. The etching agents for silicon nitride may contain phosphoric acid or compounds containing fluorine or organophosphate. The sizes of the low glass powders may be less than 200 nm, preferably less than 100 nm, and more preferably less than 50 nm. The loading concentration of glass may be from approximately 1.5% wt. to 10% wt.

The metallic nanoparticle ink may be nickel nanoparticle ink. Printed nickel ink may be sintered in an inert atmosphere or reducing environment such as hydrogen containing forming gases. The etchant in nickel etches silicon nitride and forms an ohmic contact on both n-type and p-type silicon.

1. A method for making a solar cell structure comprising:
depositing a passivation layer onto an emitter layer of a silicon substrate;
printing a metallic nanoparticle layer on the passivation layer; and
sintering the printed metallic nanoparticle layer to form low contact resistance electrodes on the emitter layer.

2. The method as recited in claim 1, further comprising incorporating an etching agent or catalyst to enable metallic nanoparticles in the printed metallic nanoparticle layer to diffuse through the passivation layer to form an ohmic contact underneath the emitter layer.

3. The method as recited in claim 1, wherein the temperature of the sintering ranges from 350° C. to 600° C.

4. The method as recited in claim 1, wherein the metallic nanoparticle layer is printed with a mixture comprising nickel nanoparticles.

5. The method as recited in claim 4, wherein the sintering includes the nickel nanoparticles reacting with silicon nitride in the passivation layer to form conductive nickel silicide.

6. The method as recited in claim 1, wherein the metallic nanoparticle layer is printed on the passivation layer with a non-contact printing technique.

7. The method as recited in claim 1, wherein the metallic nanoparticle layer is printed on the passivation layer using ink-jet printing.

8. The method as recited in claim 1, wherein the metallic nanoparticle layer is printed on the passivation layer using aerosol printing.

9. The method as recited in claim 1, wherein the metallic nanoparticle layer is printed on passivation layer using screen printing.

10. The method as recited in claim 1, wherein the sintering is thermal sintering.

11. The method as recited in claim 1, wherein the sintering is photosintering.

12. The method as recited in claim 1, wherein the electrodes are front side electrodes on the solar cell, structure.

13. The method as recited in claim 1, wherein the electrodes are back side electrodes on the solar cell structure.

14. A method for making a solar cell structure comprising;
printing a metallic nanoparticle layer on a passivation layer of a silicon substrate of the solar cell structure; and
firing the printed metallic nanoparticle layer to form low contact resistance electrodes on the emitter layer.

15. The method as recited in claim 14, wherein the temperature of the tiring ranges from 350° C. to 600° C.

16. The method as recited in claim 14, wherein the metallic nanoparticle layer is printed with a mixture comprising nickel nanoparticles, wherein the firing includes the nickel nanoparticles reacting with silicon nitride in the passivation layer to form conductive nickel suicide.

17. The method as recited in claim 14, wherein the metallic nanoparticle layer is printed on the passivation layer with a non-contact printing technique.

18. The method as recited in claim 14, wherein the metallic nanoparticle layer is printed on the passivation layer using screen printing.

19. The method as recited in claim 14, wherein the firing is thermal sintering.

20. The method as recited in claim 14, wherein the firing is photosintering.
